(19) United States
(12) Patent Application Publication
(10) Pub. No.: US 2014/0015533 A1
(43) Pub. Date: Jan. 16, 2014

(54) CURRENT SENSOR

(71) Applicants: Klaus Rink, Rodenbach (DE); Wolfgang Jöckel, Gersfeld (DE)

(72) Inventors: Klaus Rink, Rodenbach (DE); Wolfgang Jöckel, Gersfeld (DE)

(73) Assignee: CONTINENTAL TEVES AG & CO. OHG, Frankfurt (DE)

(21) Appl. No.: 14/007,700

(22) PCT Filed: Mar. 29, 2012
(86) PCT No.: PCT/EP2012/055718

§ 371 Date: Sep. 26, 2013

(30) Foreign Application Priority Data
Mar. 29, 2011 (DE) 10 2011 006 376.5

(51) Int. Cl. G01R 19/00; G01R 31/36

(52) U.S. Cl. CPC G01R 19/00; G01R 31/36
USPC 324/426; 324/713; 324/244

(57) ABSTRACT

A current sensor including at least one first current detection element, which detects a load current (I_{load}) through an electric conductor and provides an electric measurement signal in dependence on this load current, wherein the current detection element is connected to a signal processing unit, which includes a resistance element, which is configured such that, at least within a defined measurement region of the current sensor, the electrical resistance of the resistance element decreases if the load current detected by the current detection element increases.

### CROSS REFERENCE TO RELATED APPLICATIONS

This application is the U.S. National Phase Application of PCT International Application No. PCT/EP2012/055718, filed Mar. 29, 2012, which claims priority to German Patent Application No. 10 2011 006 376.5, filed Mar. 29, 2011, the contents of such applications being incorporated by reference herein.

### FIELD OF THE INVENTION

The invention relates to a current sensor comprising at least one first current detection element which detects a load current (i_{load}) through an electrical conductor and provides an electrical measurement signal on the basis of this load current.

### BACKGROUND OF THE INVENTION

Current measurements are nowadays carried out at many points in motor vehicles. These current measurements are incorporated, for example, in control loops, are used to monitor limit values or are used to measure the discharge current or charging current of a battery. In the latter field of use, the state of charge of the battery is determined, inter alia. In addition, conclusions regarding the state of the battery are drawn by monitoring the internal resistance of the battery. These include the age and capacity of the battery.

On account of the search for new drive concepts using renewable energies, numerous developments concentrate on electric and hybrid drives. The detection of the state of charge and the overall state of the battery is becoming more important here. In this case, the current and the voltage of the battery must be measured. The battery voltages are up to 1000 V in this case and the discharge currents are up to 600 A. The dynamic range of the currents to be measured extends, for example, from 10 mA to 1000 A, that is to say a factor of 1*10⁻⁵. The accuracy should often be <1%, based on the respective measured value. So that no excessively high power loss is produced, the value of the shunt resistor is limited to a maximum of 100 μΩ.

Current measurement by measuring the voltage across a non-reactive resistor (shunt) connected into the circuit is most widespread. However, in this case, it is often difficult to cover the required dynamic range with the required accuracy. For example, with a current of 10 mA, a voltage of 1 μV is dropped across the 100 μΩ resistor and must be accurately measured to 1%. With a current of 1000 A, a voltage of 100 mV is dropped and must likewise be measured in a very accurate manner. High-resolution, accurate A/D converters are required for this purpose, which is relatively expensive.

### SUMMARY OF THE INVENTION

An aspect of the invention is based on proposing a current sensor which can be used in a relatively cost-effective manner, in particular in the case of a relatively large measurement range or in the case of a relatively large dynamic range of the current to be measured.

This is achieved, according to the invention, by the current sensor comprising at least one first current detection element which detects a load current (i_{load}) through an electrical conductor and provides an electrical measurement signal on the basis of this load current, wherein the current detection element is connected to a signal processing unit comprising a resistance element which is designed in such a manner that, at least within a defined measurement range of the current sensor, the electrical resistance of the resistance element decreases if the load current detected by the current detection element increases.

One advantage of the invention is, in particular, that various current detection elements can be used in the current sensor, for example non-reactive resistors or shunts, or magnetic field sensor elements, such as Hall sensor elements or AMR elements.

It is preferred for the current sensor to be designed in such a manner that the load current detected by the current detection element is measured by virtue of a current flowing through the resistance element on the basis of the electrical measurement signal and the voltage across the resistance element being measured by an analog/digital converter.

It is preferred for the electrical measurement signal provided by the current detection element to be substantially proportional to the load current through the electrical conductor which is intended to be detected and measured.

The signal processing unit preferably comprises at least one control loop which is used to adjust the voltage across the resistance element to a defined reference voltage value, at least within a defined measurement range. In this case, the defined reference voltage value is particularly preferably at least 1 mV.

It is expedient that the signal processing unit comprises an amplifier which amplifies the electrical measurement signal on the input side and provides an output current which flows through the resistance element.

It is preferred for the signal processing unit to be designed in such a manner that the percentage resolution of the current measurement based on the instantaneous value of the load current remains substantially constant over the defined measurement range of the current sensor based on the current to be detected through the current detection element.

The current detection element is preferably in the form of a shunt, and the resistance element of the signal processing unit is not designed as a power resistance element, in particular.

Alternatively, the current detection element is preferably in the form of a magnetic field sensor element, and the resistance element of the signal processing unit is not designed as a power resistance element, in particular.

A power resistance element is preferably understood as meaning an electronic component, for example a resistance element, or a semiconductor component, such as a transistor, which is designed for current intensities of more than 1 A, in particular more than 10 A.

The resistance element of the signal processing unit is accordingly expediently designed in such a manner that it comprises only components which are designed for electrical currents of up to or at most or less than 1 A, in particular 10 A; this particularly preferably applies to partial resistance elements.

It is preferred for the voltage for detecting the current through the resistance element to be detected as a gate-source voltage or a base-emitter voltage across a transistor element of the resistance element.

It is expedient that, with a controlled reference voltage across the resistance element, the resistance value of this resistance element is substantially dependent on 1 by virtue of the value of the current through this resistance element or is substantially dependent on 1 by virtue of the root of the value of the current through this resistance element.

The current sensor is preferably designed in such a manner that the peak value of the load current through the conductor is greater than the peak value of the current through the resistance element of the signal processing unit by at least a factor of 100, in particular at least a factor of 1000. The signal processing unit is thus expediently designed in such a manner that at least its resistance element operates as a transformer and considerably reduces the dynamic range or the limits of the interval of the dynamic range of the measurement signal, for example by a factor of 1000.

The invention preferably has the advantage that the self-heating by the resistance element is low and substantially the external temperature influences are decisive for the current sensor.

It is preferred for the resistance element of the signal processing unit to comprise two or more partial resistance elements which are connected in parallel and, in particular, can be connected and/or disconnected, substantially in order to extend the measurement range.

The resistance element particularly preferably comprises a first control loop and a second control loop which are each used to adjust the voltage across a partial resistance element to a defined reference voltage value, at least within a defined measurement range, the current to be measured being able to flow through the partial resistance element of the first control loop in a first defined direction and the current to be measured being able to flow through the partial resistance element of the second control loop in a second direction opposite the first direction, and the current to be measured being detected and measured using the first control loop or the second control loop, depending on the direction of the current.

The partial resistance elements of the first and second control loops are very particularly preferably in the form of two field effect transistors which are complementary to one another, and/or the partial resistance elements of the first and second control loops are connected in parallel and the drain connection or collector connection of one partial resistance element is respectively connected to the source connection or emitter connection of the other partial resistance element here, in particular alternately.

It is expedient that the at least one partial resistance element is assigned at least one SenseFET which is connected to an analog/digital converter, the current through the resistance element being determined using the SenseFET.

It is preferred for the defined reference voltage to be adjustable in order to extend the measurement range.

An aspect of the invention also relates to the use of the current sensor in motor vehicles, in particular for measuring a discharge and/or charging current of an electrical energy store in an electric or hybrid vehicle.

### BRIEF DESCRIPTION OF THE DRAWINGS

The invention is best understood from the following detailed description when read in connection with the accompanying drawings. Included in the drawings is the following figures:

FIG. 1 shows an exemplary embodiment in which the current sensor is used to measure a discharge and/or charging current of an electrical energy store in an electric or hybrid vehicle, and

FIG. 2 shows an exemplary current sensor having a resistance element of a signal processing circuit, this resistance element comprising two partial resistance elements which are used to adjust the voltage to a defined reference voltage value using a control loop in each case.

### DETAILED DESCRIPTION OF THE PREFERRED EMBODIMENTS

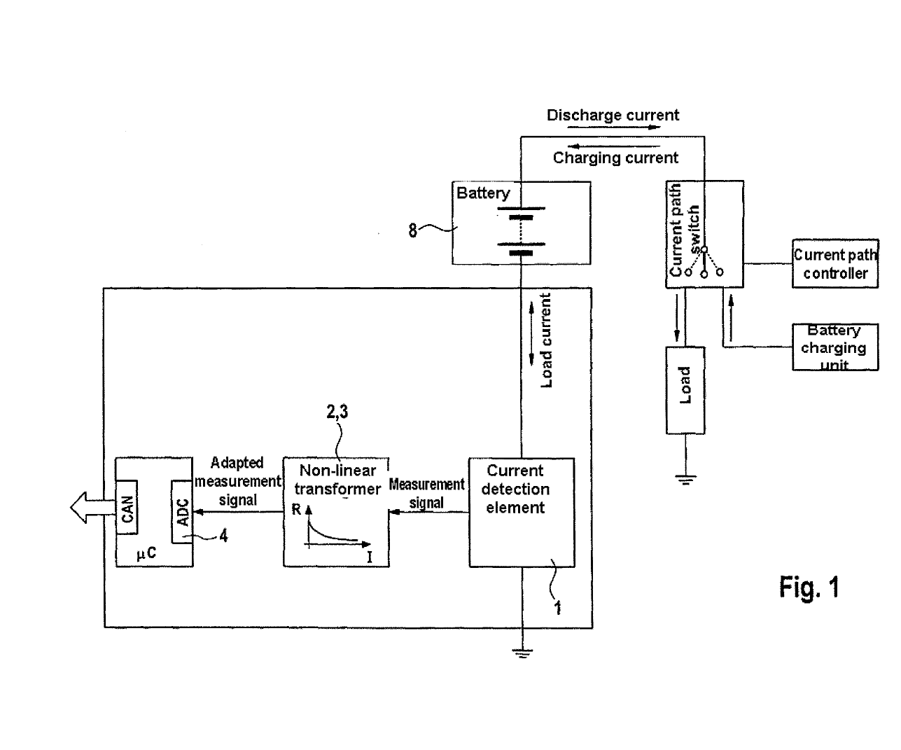

FIG. 1 shows an exemplary embodiment of the current sensor which is used to measure the discharge and charging current iₘₑₐₛ of an electrical energy store or battery 8. A current detection element 1, for example in the form of a shunt, detects the load current through the electrical conductor, which is used to connect the battery 8, and, on the basis of the load current, provides an electrical measurement signal which is supplied to a signal processing unit 2, 3 which has, for example, a non-linear transformer comprising at least one resistance element. The adapted measurement signal or the measurement signal converted by the signal processing unit 2, 3 is supplied to an analog/digital converter 4 which carries out the measurement.

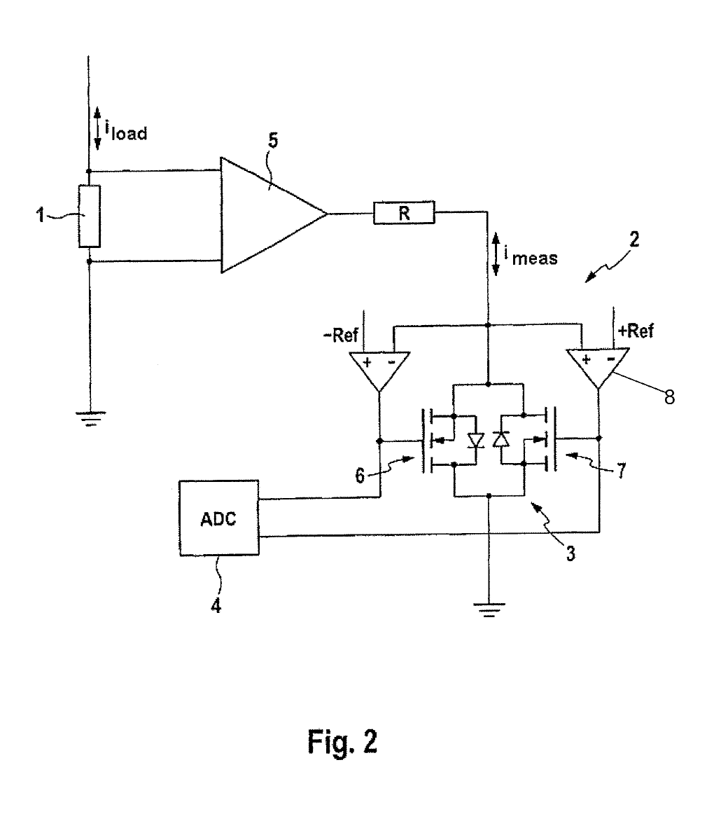

FIG. 2 illustrates an exemplary current sensor comprising a current detection element 1 which is in the form of a shunt, for example, through which the measurement current i_{load} to be detected flows and across which the voltage is tapped off as an electrical measurement signal. This voltage is applied to an amplifier 5 of the signal processing unit 2. On the basis of the input-side voltage, the amplifier 5, for example in the form of a voltage amplifier, generates at the output, in conjunction with the auxiliary resistor R, a current signal which is supplied to the resistance element 3 and flows through the resistance element 3 as the measurement current iₘₑₐₛ. In this case, the resistance element 3 comprises a first control loop and a second control loop, the first control loop comprising the left-hand partial resistance element 6, the left-hand amplifier and the reference voltage value specification −Ref associated with the latter from a reference voltage source, and the second control loop comprising the right-hand partial resistance element 7, the right-hand amplifier 4 and the corresponding reference voltage value specification +Ref. The current to be measured flows through the two partial resistance elements 6, 7 of the two control loops, the current iₘₑₐₛ flowing through the partial resistance element of the first control loop during discharging and flowing through the partial resistance element of the second control loop during charging, that is to say if the measurement current iₘₑₐₛ has the opposite direction of flow. The partial resistance elements 6, 7 of the first and second control loops are, for example, in the form of two MOS field effect transistors complementary to one another and are connected in parallel, the drain connection of one partial resistance element respectively being alternately connected to the source connection of the other partial resistance element. In this case, the drain-source voltage of the two MOSFETs is adjusted to a defined reference voltage value, as a result of which the resistance value of the two partial resistance elements, substantially dependent on 1, is characterized by the value of the current iₘₑₐₛ through the resistance element 3 and the resistance value therefore decreases with an increasing measurement current iₘₑₐₛ and the resistance value of the resistance element 3 increases with a decreasing current. In order to measure the current, the gate-source voltage of the corresponding partial resistance element is detected in this case, which voltage is the manipulated variable of the first and second control loops and is supplied to the analog/digital converter 4. The drain-source voltage to be controlled is, for example, way below the forward voltage of the parasitic diodes in each case, at a few mV.

1. -15. (canceled)

16. A current sensor comprising at least one first current detection element which detects a load current (i_{load}) through an electrical conductor and provides an electrical measurement signal on the basis of this load current, wherein the current detection element is connected to a signal processing unit comprising a resistance element which is designed in such a manner that, at least within a defined measurement range of the current sensor, the electrical resistance of the resistance element decreases if the load current detected by the current detection element increases.

17. The current sensor as claimed in claim 16, wherein the current sensor is designed in such a manner that the load current (i_{load}) detected by the current detection element is measured by virtue of a current flowing through the resistance element on the basis of the electrical measurement signal and the voltage across the resistance element being measured by an analog/digital converter.

18. The current sensor as claimed in claim 16, wherein the signal processing unit comprises at least one control loop which is used to adjust the voltage across the resistance element to a defined reference voltage value, at least within a defined measurement range.

19. The current sensor as claimed in claim 18, wherein the defined reference voltage value is at least 1 mV.

20. The current sensor as claimed in claim 18, wherein the signal processing unit comprises an amplifier which amplifies the electrical measurement signal on the input side and provides an output current which flows through the resistance element.

21. The current sensor as claimed in claim 16, wherein the signal processing unit is designed in such a manner that the percentage resolution of the current measurement based on the instantaneous value of the load current remains substantially constant over the defined measurement range of the current sensor based on the current to be detected through the current detection element.

22. The current sensor as claimed in claim 16, wherein the current detection element is in the form of a shunt, and the resistance element of the signal processing unit is not designed as a power resistance element.

23. The current sensor as claimed in claim 16, wherein the current detection element is in the form of a magnetic field sensor element, and the resistance element of the signal processing unit is not designed as a power resistance element.

24. The current sensor as claimed in claim 16, wherein the voltage for detecting the current through the resistance element is detected as a gate-source voltage or a base-emitter voltage across a transistor element of the resistance element.

25. The current sensor as claimed in claim 18, wherein with a controlled reference voltage across the resistance element, the resistance value of the resistance element is substantially dependent on 1 by virtue of the value of the current through the resistance element or is substantially dependent on 1 by virtue of the root of the value of the current through this resistance element.

26. The current sensor as claimed in claim 16, wherein the resistance element comprises two or more partial resistance elements which are connected in parallel and can be connected and/or disconnected, substantially in order to extend the measurement range.

27. The current sensor as claimed in claim 26, wherein the resistance element comprises a first control loop and a second control loop which are each used to adjust the voltage across a partial resistance element to a defined reference voltage value, at least within a defined measurement range, the current to be measured being able to flow through the partial resistance element of the first control loop in a first defined direction and the current to be measured being able to flow through the partial resistance element of the second control loop in a second direction opposite the first direction, and the current to be measured being detected and measured using the first control loop or the second control loop, depending on the direction of the current.

28. The current sensor as claimed in claim 27, wherein the partial resistance elements of the first and second control loops are in the form of two field effect transistors which are complementary to one another, and/or the partial resistance elements of the first and second control loops are connected in parallel and the drain connection or collector connection of one partial resistance element is respectively connected to the source connection or emitter connection of the other partial resistance element alternately.

29. The current sensor as claimed in claim 26, wherein the at least one partial resistance element is assigned at least one SenseFET which is connected to an analog/digital converter, the current through the resistance element being determined using the SenseFET.

30. The use of the current sensor as claimed in claim 16 in motor vehicles, for measuring a discharge and/or charging current of an electrical energy store in an electric or hybrid vehicle.
